(19) United States
(12) Patent Application Publication
(10) Pub. No.: US 2011/0203103 A1
(43) Pub. Date: Aug. 25, 2011

(54) METHOD OF INSTALLING A CAPACITOR TO A SERVICE ENTRANCE PANEL TO REDUCE KW CONSUMPTION

(76) Inventor: Steven Bruce Fish, Port Orange, FL (US)

(21) Appl. No.: 13/035,911

(22) Filed: Feb. 25, 2011

Related U.S. Application Data
(60) Provisional application No. 61/307,955, filed on Feb. 25, 2010.

(51) Int. Cl. H05K 13/00

(52) U.S. Cl. 29/592.1

(57) ABSTRACT

A method for installing a power factor correcting circuit to be applied at the electric service panel of a facility is disclosed which is comprised of a series of measurements under controlled load conditions, and a series of installation steps. The method of the invention is comprised of power factor measurements taken under minimum load conditions, single reactive load conditions, and full load conditions. The method of the invention applies to single and poly-phase electrical systems.

### CROSS REFERENCE TO RELATED APPLICATIONS

This patent application incorporates by reference, in its entirety, and claims the benefit of the filing date of U.S. Provisional Patent Application Ser. No. 61/307,955, METHOD OF INSTALLING A CAPACITOR TO A SERVICE ENTRANCE PANEL TO REDUCE KW CONSUMPTION, filing date Feb. 25, 2010.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISK

Not Applicable

### BACKGROUND OF THE INVENTION

1. Field of the Invention

The Invention relates to the field of power factor correction in general. The present invention is directed to a method for installing power factor correcting circuitry at a power utility service entrance panel of a facility for single or poly-phase systems in order to reduce the energy consumption of the facility by increasing electrical power factor. The benefits of the invention include increased power factor, increased efficiency, reduced energy consumption, and reduced energy costs.

The power factor of an AC electric power system is defined as the ratio of the real power flowing to the load to the apparent power in the circuit, and is a dimensionless number between 0 and 1 (frequently expressed as a percentage, e.g. 0.5 pf=50% pf). Real power is the capacity of the circuit for performing work in a particular time. Apparent power is the product of the current and voltage of the circuit. Due to energy stored in the load and returned to the source, or due to a non-linear load that distorts the wave shape of the current drawn from the source, the apparent power will usually be greater than the real power in any real application.

In an electric power system, a load with a low power factor draws more current than a load with a high power factor for the same amount of useful power transferred. The higher currents in the low power factor system increase the energy lost in the distribution system, and require larger (i.e. more expensive) wires and other equipment. Because of the costs of larger equipment and wasted energy, electrical utilities will usually charge a higher cost to industrial or commercial customers where there is a low power factor.

Linear loads with low power factor (such as induction motors) can be corrected with a passive network of capacitors or inductors. Non-linear loads, such as rectifiers, distort the current drawn from the system. In such cases, active or passive power factor correction may be used to counteract the distortion and raise the power factor. The devices for correction of the power factor may be at a central substation, spread out over a distribution system, installed at the power service entrance of the facility, or built into power-consuming equipment.

It is usually desirable to adjust the power factor of a system to near 1.0. This power factor correction (PFC) is typically achieved by switching in or out banks of inductors or capacitors depending upon the specific current and voltage waveforms for the particular application. For example the inductive effect of motor loads may be offset by locally connected capacitors. When reactive elements supply or absorb reactive power near the load, the apparent power is reduced.

Power factor correction may be applied by an electrical power transmission utility to improve the stability and efficiency of the transmission network. Correction equipment may be installed by individual electrical customers to reduce the costs charged to them by their electricity supplier. A high power factor is generally desirable in a transmission system to reduce transmission losses and improve voltage regulation at the load.

2. Background

Power factor correction brings the power factor of an AC power circuit closer to 1 by supplying reactive power of opposite sign, adding capacitors or inductors which act to cancel the inductive or capacitive effects of the load, respectively. For example, the inductive effect of motor loads may be offset by locally connected capacitors. If a load had a capacitive value, inductors (also known as reactors in this context) are connected to correct the power factor. In the electricity industry, inductors are said to consume reactive power and capacitors are said to supply it, even though the reactive power is actually just moving back and forth on each AC cycle.

The reactive elements can create voltage fluctuations and harmonic noise when switched on or off. They will supply or sink reactive power regardless of whether there is a corresponding load operating nearby, increasing the system's no-load losses. In a worst case, reactive elements can interact with the system and with each other to create resonant conditions, resulting in system instability and severe overvoltage fluctuations. As such, reactive elements cannot simply be applied at will, and power factor correction is normally subject to engineering analysis or testing to appropriately size the reactive elements.

There are, in the art, capacitors intended to be installed in a facility; for example residences, commercial buildings, or the like. Most such prior art solutions incorporate a “one size fits all” solution. Some involve plugging a capacitor into an electrical outlet, while others involve installation at the main breaker panel. However, no two facilities are comprised of exactly the same load: therefore to achieve a truly optimized power factor correction for a particular facility, it is desirable to ascertain the effect of improving power factor by taking measurements under various load conditions. If the wrong value power factor correcting components are installed, there can actually be an increase in electricity costs for a given facility.

The concept of adding capacitance to correct for power factor is known in the art. One of the most typical applications is to install capacitor(s) at the service entrance of a facility. In many instances these capacitors may be a fixed value or they may comprise a system that switches capacitors in and out to keep the power factor within a certain range.

The method of the invention overcomes the prior “one size fits all” power factor correction methods, and overcomes the difficulties of ascertaining the correct capacitance needed to optimize power factor correction.

The usual electrical service coming in from the utility is 240-volts AC supplied as two 120-volt circuits, 180-degrees out of phase on three wires, two hot and one neutral. These three wires carry first through a utility meter comprised of a round glass enveloped instrument with a spinning disk inside that shows the rate at which the home is consuming power. The face of the meter has several dials or other readouts that register the total power consumption in kilo-watt hours (kWh). After the meter, a main disconnect tandem circuit breaker connects to a distribution panel with many branch circuit breakers.

The present invention overcomes the “one size fits all” limitation of the prior art by providing a method for optimizing the capacitance (or inductance) that is applied at the service panel to achieve power factor correction for the power delivered to the facility.

Additionally, all patents, patent applications and publications discussed or cited herein are incorporated by reference to the same extent as if each individual publication or patent application was specifically and individually set forth herein in its entirety.

### BRIEF SUMMARY OF THE INVENTION

The present invention overcomes the drawbacks of the aforementioned inventions. A method for installing power factor correcting circuitry to be applied at the electric service panel of a facility is disclosed which is comprised of a series of measurements under controlled load conditions. While the method discussed in the preferred embodiment of the system involves power factor correction utilizing capacitance, it is easily understood that the same method can be used to provide inductance required in those systems which require inductance for power factor correction.

### BRIEF DESCRIPTION OF THE DRAWINGS

FIG. 1A depicts an exemplary first part of a method sheet for performing the steps of the invention in a single phase system.

FIG. 1B depicts an exemplary second part of a method sheet for performing the steps of the invention in a single phase system.

FIG. 1C depicts an exemplary third part of a method sheet for performing the steps of the invention in a single phase system.

FIG. 2A depicts an exemplary first part of a method sheet for performing the steps of the invention in a three phase system.

FIG. 2B depicts an exemplary second part of a method sheet for performing the steps of the invention in a three phase system.

FIG. 2C depicts an exemplary third part of a method sheet for performing the steps of the invention in a three phase system.

FIG. 3 depicts a single phase power factor correcting panel unit.

FIG. 4 depicts a three phase power factor correcting panel unit.

### DETAILED DESCRIPTION OF THE INVENTION

The following steps are generally followed. Although the steps herein are listed in a particular order in this description, it should be understood that the sequence of the steps of the method may be interchanged.

The method of the invention is typically, but not as a limitation, used once it has been determined that there is no cost-effective solution of installing power factor correction to individual loads within the facility. Any loads that are cost effectively corrected at the individual motor load should be done there, and installed, or at least the sizing units still hooked up to in order to approach the panel units (if there are custom units to be installed, they have to be done prior to any panel units being sized). A panel unit should typically not be sized when it expected that additional capacitors are to be added to any of the individual loads connected to that panel. Once all the capacitors are installed on the loads of the system that are attached to the panel, the capacitance at the panel can be sized.

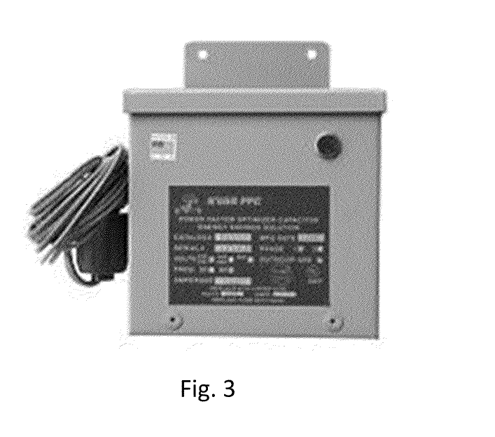

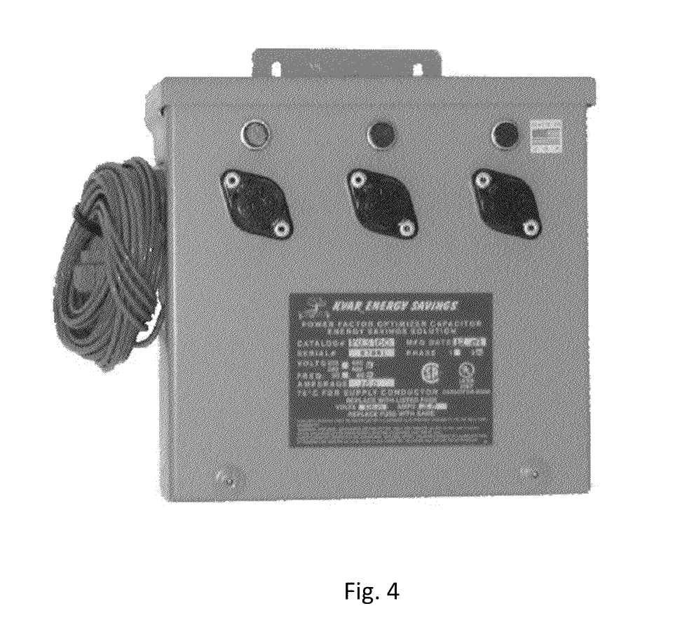

“Panel Units” as used herein means power factor correcting circuit elements, such as capacitors, housed within an electrical enclosure containing provisions for electrically connecting to electrical service breaker panels, as shown in FIG. 3 for a single phase system, and FIG. 4 for a three phase system. Such electrical enclosures and methods for making electrical connections are known in the art of the electric power service trade. Panel Units (PUs) types are selected for installation based number of phase and current carrying capacity.

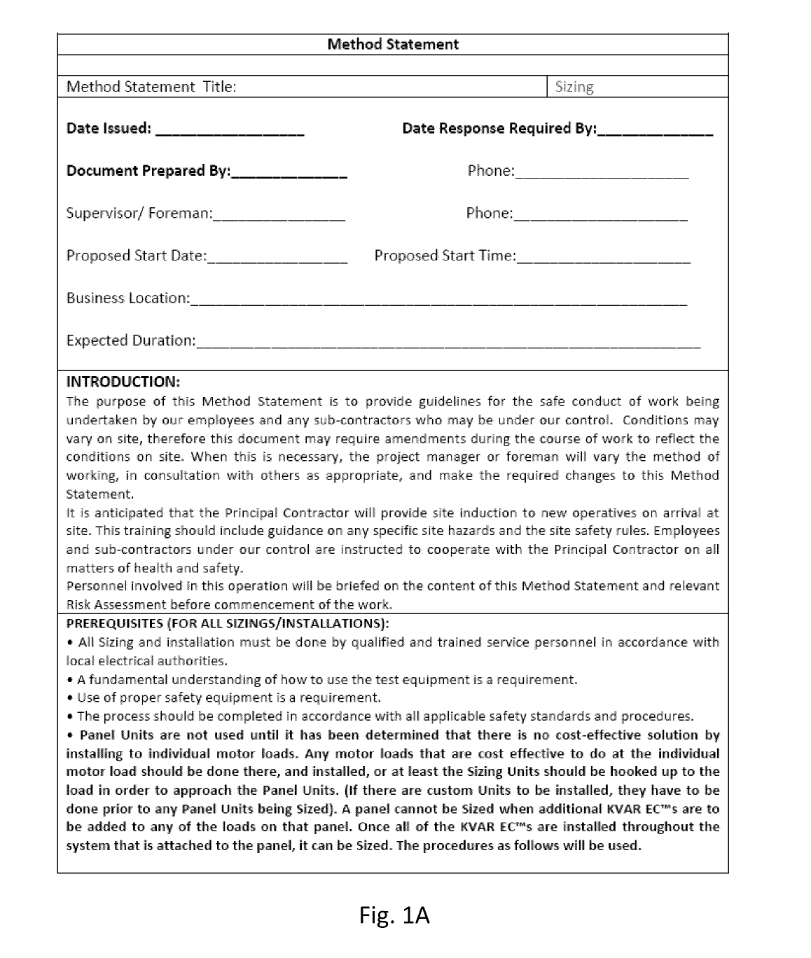

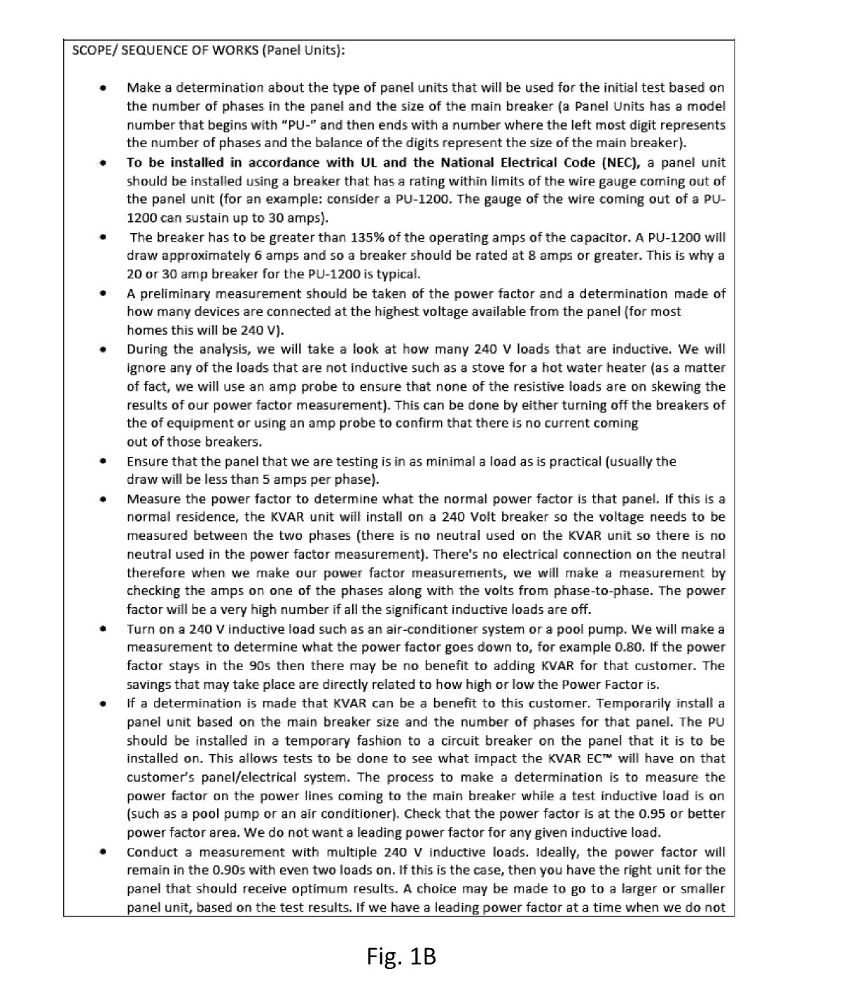

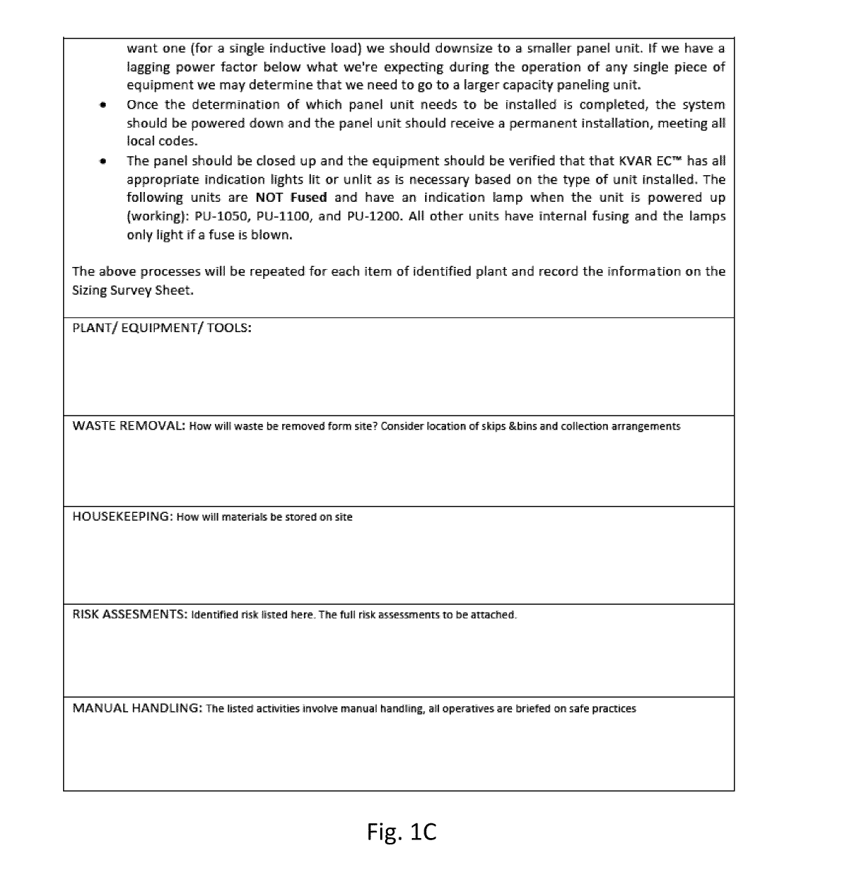

Referring to FIGS. 1A, 1B, and 1C it is seen that a specific installation method may be used on a single phase system as depicted therein.

A first step is to gather the materials and equipment required, which are:
a. a power factor meter that will measure power factor on the type of panel that is being sized. Single phase=power quality meter or power harmonics meter.
b. Panel units for the type of panel that the equipment will be installed in.

A second step is to make a determination about the type of panel units that will be used for the initial test based on the number of phases in the panel and the size of the main breaker. A panel unit typically has a model number that begins with “PU-” and then ends with a number where the left most digit represents the number of phases and the balance of the digits represent the size of the main breaker.

A panel unit should be installed using a breaker that is rated within limits of the wire gauge coming out of the panel unit. By way of example, consider a single phase PU. The gauge of the wire coming out of a single phase PU can typically sustain up to 30 amps. As a result a single phase PU can be installed on a 30 amp breaker or less. The breaker should be greater than 135% of the operating amps of the capacitor. A single phase PU will typically draw approximately 6 amps thus a breaker for use with a single phase PU should be rated at 8 amps or greater. A 20 or 30 amp breaker for the PU1200 is typical. A preliminary measurement should be taken of the power factor and a determination made of how many devices are connected at the highest voltage available from the panel. For most facilities the highest voltage will be 240 VAC.

A next step is to determine how many loads on the panel are inductive. All loads, including purely resistive loads, such as a hot water heater, are switched off during this step. An ampere probe is used to ensure that none of the resistive loads are on, which would lead to a skewing the results of the power factor measurement. This can be done by either turning off the breakers of those types of equipment or using an amp probe to confirm that there is no current on the load side of those breakers.

A power factor measurement is then taken at this minimum load condition to determine the typical power factor for that panel. For a typical normal residence, the adapter will install on a 240 VAC panel so the voltage needs to be measured between the two phases (there is no neutral used on the adapter unit so there is no neutral used in the power factor measurement). There is no electrical connection on the neutral, therefore the power factor measurements will be made by checking the amps on one of the phases along with the volts from phase-to-phase. The power factor will be a very high number if all the significant inductive loads are off.

A next step is to turn on a 240 V inductive load such as an air-conditioner system or a pool pump. A measurement is made to determine the power factor for this state, for example 0.80. If the power factor stays in the 0.90s then there may be no benefit of power factor correction for that user.

If a determination is made that power factor correction can be a benefit to this facility, the next step is to temporarily install a panel unit (PU) based on the main breaker size and the number of phases for that panel. The PU should be installed in a temporary fashion to a circuit breaker on the panel on which it is to be installed. This allows tests to be done to see what impact the adapter will have on that panel/electrical system. The process to make a determination is to measure the power factor on the power lines coming to the main breaker while a test inductive load is on, such as a pool pump or an air conditioner, and see that the power factor is 0.95 or better. It is not desirable to have a leading power factor for any given inductive load.

Next, a measurement is made with multiple 240 V inductive loads turned on and drawing power. Ideally, the power factor will remain in the 0.90s with even two loads on. If this is the case, then the correct adapter for the panel has been chosen. A choice may be made to go to a larger or smaller capacitance Panel Unit, based on the test results. If there is a leading power factor at a time when it is not desired (for a single inductive load) the panel unit capacitance should be reduced. If there is a lagging power factor below what was expecting during the operation of any single piece of equipment it may be determined that a larger capacitance panel unit is required.

Once the determination of which panel unit needs to be installed is completed, the system should be powered down and the panel units should receive a permanent installation, meeting all local electrical codes. Then the panel should be closed up and the equipment should be verified that that adapter unit has all appropriate indication lights lit or unlit as is necessary based on the type of unit installed.

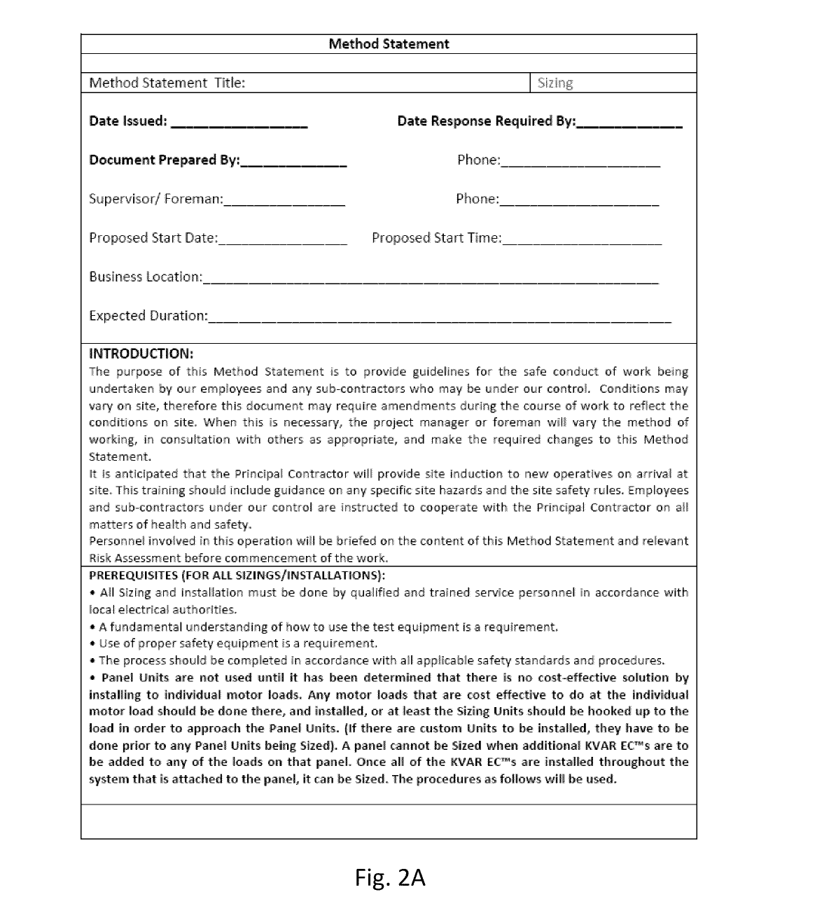

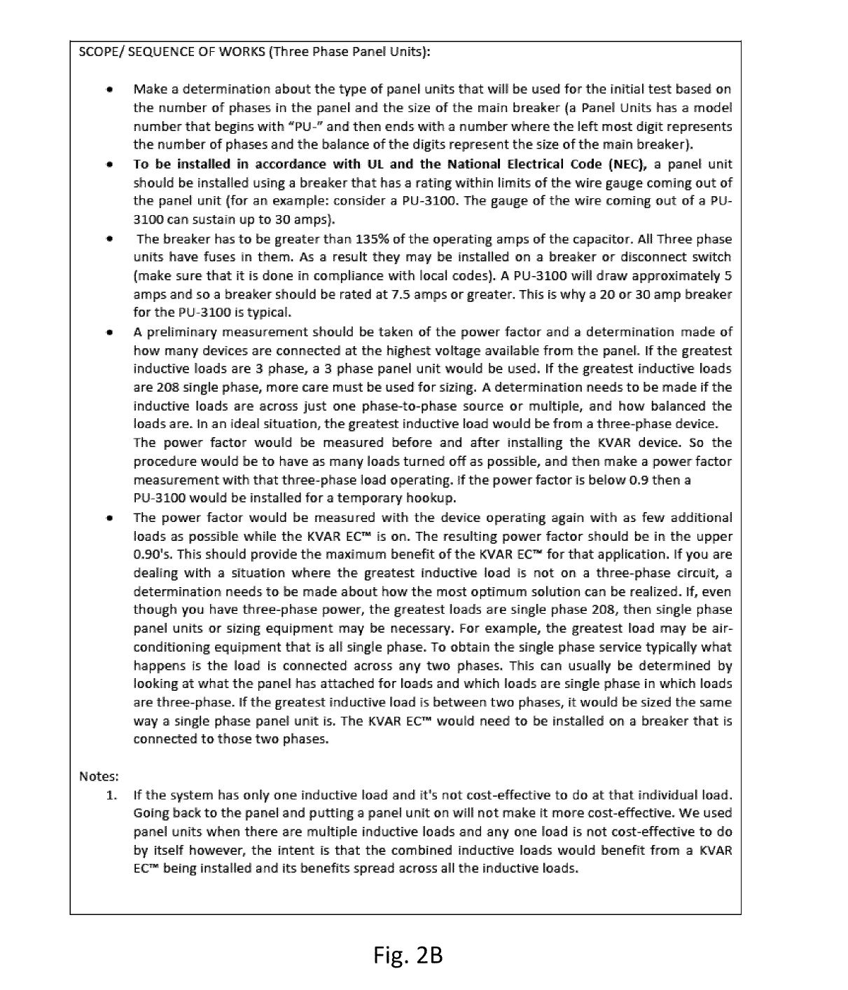

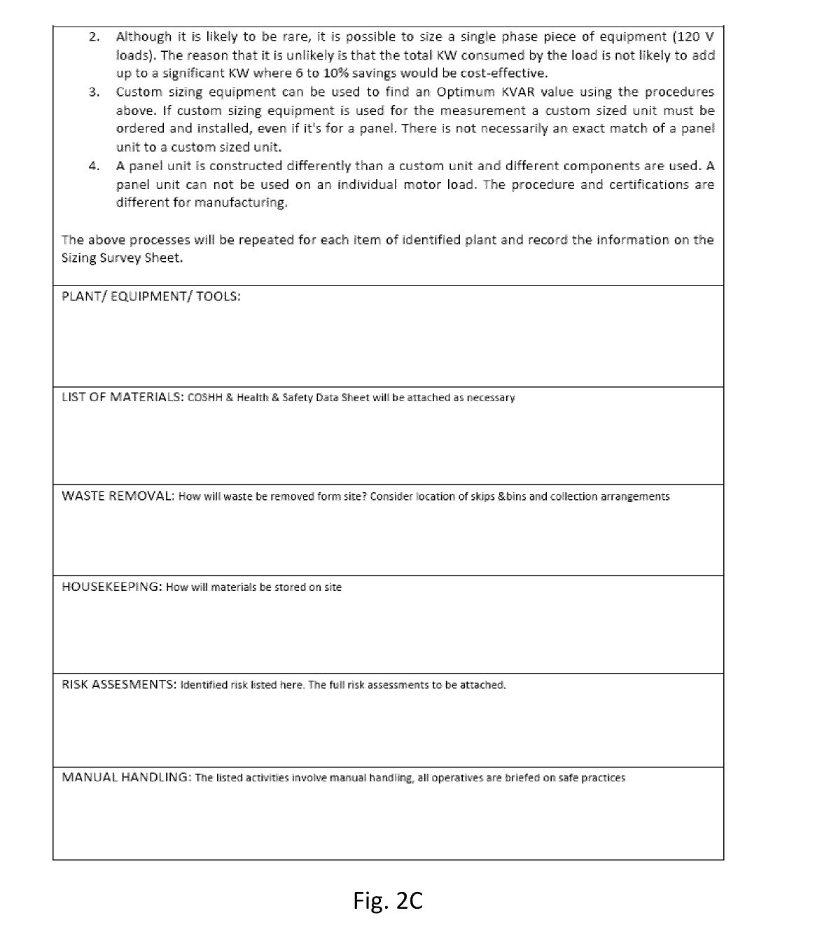

The above method may also be extended to a three-phase application. Referring to FIGS. 2A, 2B, and 2C it is seen that a specific installation method may be used on a three phase system as depicted therein.

A first step is to gather the materials and equipment required, which are:
a. a power factor meter that will measure power factor on the type of panel that is being sized. Three-phase=power harmonics meter.
b. Panel units for the type of panel that the equipment will be installed in.

A second step is to make a determination about the type of panel units that will be used for the initial test based on the number of phases in the panel and the size of the main breaker. A panel unit typically has a model number that begins with “PU-” and then ends with a number where the left most digit represents the number of phases and the balance of the digits represent the size of the main breaker.

To be installed in accordance with UL and the National Electrical Code (NEC), a panel unit should be installed using a breaker that has a rating within limits of the wire gauge coming out of the panel unit (for an example: consider a three phase PU. The gauge of the wire coming out of a three phase PU typically can sustain up to 30 amps).

The breaker has to be greater than 135% of the operating amps of the capacitor. All three phase units have fuses in them. As a result they may be installed on a breaker or disconnect switch (make sure that it is done in compliance with local codes). A three phase PU will draw approximately 5 amps and so a breaker should be rated at 7.5 amps or greater. This is why a 20 or 30 amp breaker for a three phase PU is typical.

As a next step, a preliminary measurement is taken of the power factor and a determination made of how many devices are connected at the highest voltage available from the panel. If the greatest inductive loads are 3 phase, a 3 phase panel unit should be used. If the greatest inductive loads are 208 single phase, more care must be used for sizing. A determination needs to be made if the inductive loads are across just one phase-to-phase source or multiple, and how balanced the loads are. In an ideal situation, the greatest inductive load would be from a three-phase device.

The power factor should be measured before and after installing the power factor correcting device. The procedure would be to have as many loads turned off as possible, and then make a power factor measurement with that three-phase minimum load condition. If the power factor is below 0.9 then a three phase PU would be installed for a temporary hookup.

The power factor would be measured with the device operating again with as few additional loads as possible while the three phase PU is on. The resulting power factor should be in the upper 0.90's. This should provide the maximum benefit of the three phase PU for that application. If the greatest inductive load is not on a three-phase circuit, a determination needs to be made about how the most optimum solution can be realized. If the greatest loads are single phase 208, then single phase panel units or sizing equipment may be necessary. For example, the greatest load may be air-conditioning equipment that is all single phase. To obtain the single phase service the load is typically connected across any two phases. This can usually be determined by observing at what the panel has attached for loads and which loads are single phase and which loads are three-phase. If the greatest inductive load is between two phases, the single phase PU would need to be installed on a breaker that is connected to those two phases.

Although the present invention has been described in terms of the presently preferred embodiments, it is to be understood that the disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the true spirit and scope of the invention.

I claim:

1. A method for installing a power factor correcting panel unit for correcting power factor in an electrical system comprised of one or more inductive loads in a single phase system, said method comprising;
making an initial selection of a single phase power factor correcting panel unit having an electrical capacitance based upon the amperage of the panel;
turning off as many of the loads of the system as possible;
installing said single phase power factor correcting panel unit across the single phase of the system;
making a first power factor measurement using said power factor meter;
turning on an first inductive load; and
making a second power factor measurement using said power factor meter.

2. The installation method of claim 1, further comprising the steps of:
turning on a second inductive load; and
making a third power factor measurement using said power factor meter.

3. The installation method of claim 2, further comprising the steps of:
reducing said capacitance if said third power factor measurement indicates a leading power factor.

4. The installation method of claim 2, further comprising the steps of:
increasing said capacitance if said third power factor measurement indicates a power factor less than a predetermined value.

5. A method for installing a power factor correcting panel unit for correcting power factor in an electrical system comprised of one or more inductive loads in a three phase system, said method comprising;
making an initial selection of a three phase power factor correcting panel unit having an electrical capacitance based upon the amperage of the panel;
turning off as many of the loads of the system as possible;
installing said three phase power factor correcting panel unit across the three phases of the system;
making a first power factor measurement using said power factor meter;
turning on an first inductive load; and
making a second power factor measurement using said power factor meter.

6. The installation method of claim 5, further comprising the steps of:
turning on a second inductive load; and
making a third power factor measurement using said power factor meter.

7. The installation method of claim 6, further comprising the steps of:
reducing said capacitance if said third power factor measurement indicates a leading power factor.

8. The installation method of claim 6, further comprising the steps of:
increasing said capacitance if said third power factor measurement indicates a power factor less than a predetermined value.
